(19) United States
(12) Patent Application Publication
(10) Pub. No.: US 2010/0227524 A1
(43) Pub. Date: Sep. 9, 2010

(54) METHOD OF MANUFACTURING ORGANIC LIGHT EMITTING DIODE DISPLAY DEVICE

(75) Inventors: Sun-Young Jung, Yongin-city (KR); Seung-Han Lee, Yongin-city (KR); Seung-Yong Song, Yongin-city (KR); Young-Seo Choi, Yongin-city (KR); Jin-Hwan Jeon, Yongin-city (KR); Oh-June Kwon, Yongin-city (KR); Young-Cheol Joo, Yongin-city (KR); Ji-Hun Ryu, Yongin-city (KR); Ji-Young Moon, Yongin-city (KR); Chang-Suk Park, Yongin-city (KR)

Correspondence Address: STEIN MCEWEN, LLP, 1400 EYE STREET, NW, SUITE 300, WASHINGTON, DC, 20005, US

(73) Assignee: Samsung Mobile Display Co., Ltd., Suwon-si (KR)

(21) Appl. No.: 12/713,763

(22) Filed: Feb. 26, 2010

(30) Foreign Application Priority Data
Mar. 3, 2009 (KR) 10-2009-0018202

(51) Int. Cl. H01J 9/26

(52) U.S. Cl. 445/25

(57) ABSTRACT

A method of manufacturing an organic light emitting diode (OLED) display device including a first substrate having a pixel region, and a second substrate attached to the first substrate, to seal the pixel region, the method including: applying a frit to a region of the second substrate; applying a laser beam to the frit, to plasticize the frit; aligning the first substrate and the second substrate; and applying a laser beam to the frit, to attach the first and second substrates.

### CROSS-REFERENCE TO RELATED APPLICATION

This application claims the benefit of Korean Patent Application No. 10-2009-0018202, filed Mar. 3, 2009, the disclosure of which is incorporated herein, by reference.

### BACKGROUND OF THE INVENTION

1. Field of the Invention

Aspects of the present invention relate to a method of manufacturing an organic light emitting diode display device.

2. Description of the Related Art

In recent times, among various flat panel display devices, organic light emitting diode (OLED) display devices have attracted particular attention. OLED display devices are self-emission display devices, in which organic compounds having fluorescent characteristics are disposed between opposing electrodes. A voltage is applied between the electrodes to electrically excite the organic compound, thereby emitting light. The OLED display devices can be driven at a low voltage, are simple to manufacture using a thin film process, have a wide viewing angle, and have a fast response speed.

An OLED display device generally includes: a device substrate, on which at least one organic light emitting diode is formed; an encapsulation substrate attached to the device substrate, to encapsulate the organic light emitting diode; and a frit to attach the device substrate to the encapsulation substrate. In a process of attaching the device substrate to the encapsulation substrate, the frit is applied as a paste, to a region of the device substrate that is attached to the encapsulation substrate.

Subsequently, the frit paste is pre-plasticized to remove moisture and/or binder elements there from. Then, after the encapsulation substrate is aligned on the device substrate, the frit-applied region is locally heated, using a laser beam, so as to melt the frit, thereby attaching the device substrate to the encapsulation substrate.

A process of plasticizing the frit applied to the device substrate produces different peak temperatures, according to the inherent characteristics of the frit. The process includes a total processing time of about 2 to 5 hours, or more, and includes the combustion termination time for a binder and the time for the completion of each operation. In addition, a separate furnace is needed for the plasticization, which occupies a substantial amount of factory space.

### SUMMARY OF THE INVENTION

Aspects of the present invention provide a method of manufacturing an organic light emitting diode (OLED) display device, which has a reduced processing time and production costs, and improves spacial efficiency, by using a laser beam for plasticization.

According to an exemplary embodiment of the present invention, provided is a method of manufacturing an OLED display device, having a first substrate having a pixel region, and a second substrate attached to the first substrate, to seal the pixel region, the method including: applying a frit to a region of the second substrate; applying a laser beam to the frit, to plasticize the frit; aligning the first substrate and the second substrate; and applying a laser beam to the frit, to attach the first and second substrates.

According to an exemplary embodiment of the present invention, before the plasticizing of the frit, the frit may be dried.

According to an exemplary embodiment of the present invention, the frit may be applied by screen-printing or dispensing.

According to an exemplary embodiment of the present invention, the plasticizing of the frit may be performed in the temperature range of about 300 to about 700° C.

According to an exemplary embodiment of the present invention, the laser beams applied during the plasticizing and attachment may have an intensity of 20 to 50 W.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the exemplary embodiments, taken in conjunction with the accompanying drawings, of which:

FIGS. 1 to 3 are views showing a method of manufacturing an organic light emitting diode (OLED) display device, according to an exemplary embodiment of the present invention; and

FIG. 4 is a cross-sectional view of an OLED display device that manufactured by a manufacturing method, according to an exemplary embodiment of the present invention.

### DETAILED DESCRIPTION OF THE EXEMPLARY EMBODIMENTS

Reference will now be made in detail to the exemplary embodiments of the present invention, examples of which are illustrated in the accompanying drawings, wherein like reference numerals refer to like elements throughout. The exemplary embodiments are described below, in order to explain the aspects of the present invention, by referring to the figures.

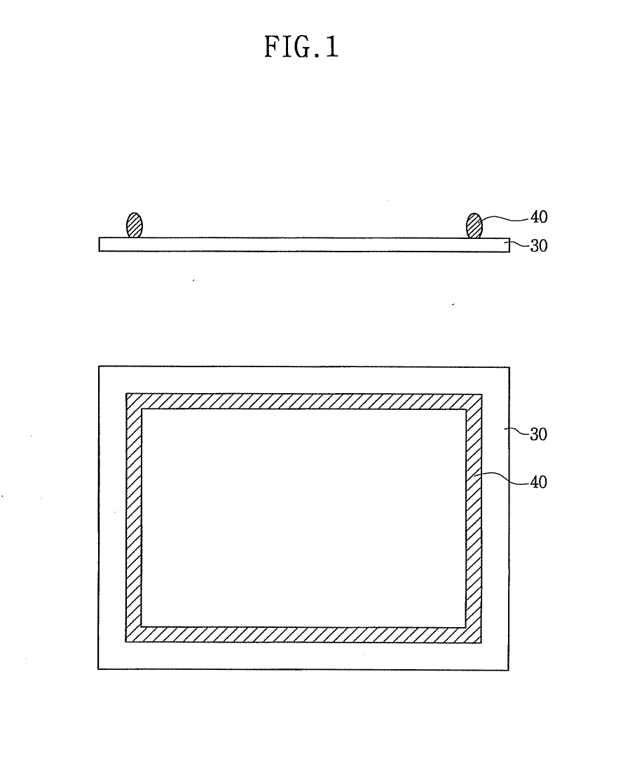

FIGS. 1 to 3 are views showing a method of manufacturing an organic light emitting diode (OLED) display device, according to an exemplary embodiment of the present invention. Referring to FIGS. 1 to 3, an OLED display device includes a first substrate 10, including a pixel region 20, in which at least one organic light emitting diode is formed to display a predetermined image, and a second substrate 30 attached to the first substrate 10, to seal the pixel region 20.

As shown in FIG. 1, a frit 40, which is glass powder having a low melting point, is applied as a paste, to a predetermined thickness, to a region of the second substrate 30 that will be attached to the first substrate 10. Generally, the frit 40 is applied along edges of a surface of the second substrate 30 that faces the first substrate 10. Herein, “frit” may refer to both the frit 40 and the paste for forming the frit 40.

The application of the frit 40 may be performed by various methods, but generally performed by screen-printing or dispensing, to a thickness that is determined by a final gap between the first substrate 10 and the second substrate 30. In addition, the frit 40 is applied to an area of the second substrate 30, so as not to damage the organic light emitting diode in the pixel region 20, by the laser beam.

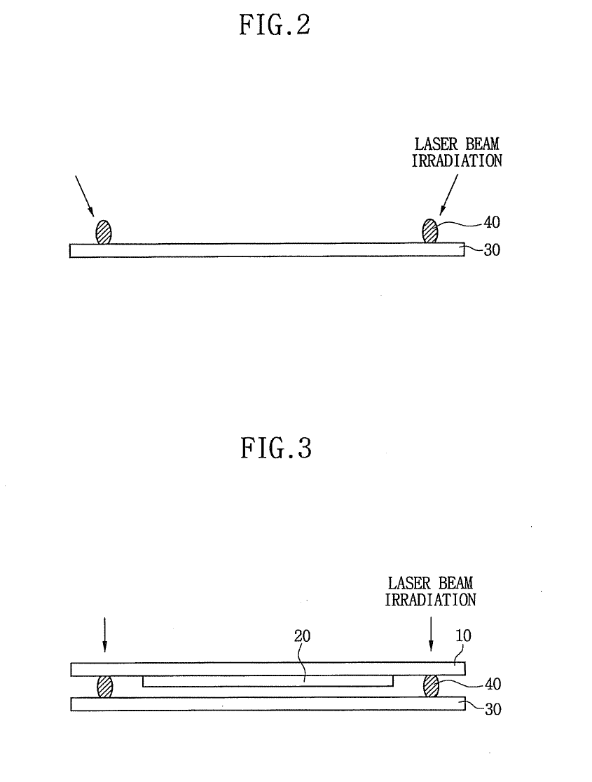

As shown in FIG. 2, a laser beam is applied to the frit 40 applied to the second substrate 30, to plasticize the frit 40, thereby removing moisture and/or binder elements from the frit 40. The plasticizing of the frit 40 may include heating the frit to a temperature ranging from about 300 to about 700° C.

The laser beam may be an infrared laser beam. The intensity of the laser beam may be adjusted according to the properties, thickness, and plasticization temperature of the frit 40. In particular, the intensity of the laser may range from 20 to 50 W.

As described above, the frit 40 may be plasticized using a laser beam, thereby rapidly increasing the temperature of, and reducing time taken to plasticize, the frit 40. Before plasticizing the frit 40, the frit 40 may be dried.

As shown in FIG. 3, the first substrate 10 and the second substrate 30 are aligned, and a laser beam is locally applied to the frit-applied region, to attach the first substrate 10 to the second substrate 30, thereby completely sealing a gap between the first substrate 10 and the second substrate 30. The laser beam may be an infrared laser beam, and an intensity of the laser beam may range from 20 to 50 W. The laser beam may be radiated through the first substrate 10, through the second substrate 30, and/or between the first and second substrates 10, 30. The above laser beams may be produced by the same laser source, or different laser sources.

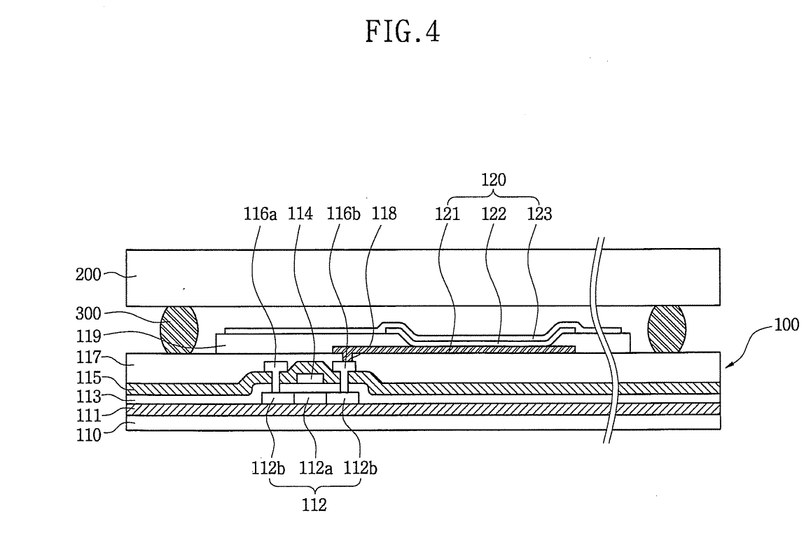

FIG. 4 is a cross-sectional view of an OLED display device, manufactured according to the manufacturing method. Referring to FIG. 4, the OLED display device includes a first substrate 100 including at least one organic light emitting diode 120, and a second substrate 200 attached to the first substrate 100, to seal the organic light emitting diode 120.

A buffer layer 111 is formed on a deposition substrate 110. The deposition substrate 110 is formed of glass, and the buffer layer 111 is formed of an insulating material, such as silicon oxide (SiO₂) or silicon nitride (SiNₓ). The buffer layer 111 protects the deposition substrate 110 from damage, for example, heat damage.

A semiconductor layer 112, having an active layer 112a and source and drain regions 112b, is formed on the buffer layer 111. A gate insulating layer 113 is formed on the buffer layer 111 and the semiconductor layer 112. A gate electrode 114 is formed on the gate insulating layer 113, facing the active layer 112a.

An interlayer insulating layer 115 is formed on the gate insulating layer 113 and the gate electrode 114. Holes are formed in the gate insulating layer 113 and the interlayer insulating layer 115, to expose the source and drain regions 112b. Source and drain electrodes 116a and 116b are formed on the interlayer insulating layer 115 and are connected to the source and drain regions 112b, via the holes.

A planarization layer 117 is formed on the interlayer insulating layer 115 and the source and drain electrodes 116a and 116b. A first electrode 121 is formed on a portion of the planarization layer 117, and is connected to one of the source and drain electrodes 116a and 116b, via a hole 118 formed in the planarization layer 117.

A pixel defining layer 119 is formed on the planarization layer 117 and the first electrode 121. The pixel defining layer 119 has a hole (not shown) exposing the first electrode 121. An organic layer 122 is formed in the hole of the pixel defining layer 119, and a second electrode 123 is formed on the pixel defining layer 119 and the organic layer 122. The second substrate 200 is attached to the first substrate 100, using a frit 300, to protect the above-mentioned structures from external substances, such as oxygen, hydrogen, and moisture.

According to various embodiments, a processing time and production costs of manufacturing an organic light emitting diode display device can be reduced, and a spatial efficiency can be improved.

Although a few exemplary embodiments of the present invention have been shown and described, it would be appreciated by those skilled in the art that changes may be made in these exemplary embodiments, without departing from the principles and spirit of the invention, the scope of which is defined in the claims and their equivalents.

What is claimed is:

1. A method of manufacturing an organic light emitting diode (OLED) display device including a first substrate having a pixel region, and a second substrate attached to the first substrate to seal the pixel region, the method comprising:
applying a frit to a region of the second substrate;
plasticizing the frit, by applying a laser beam to the frit;
aligning the first substrate and the second substrate; and
applying a laser beam to the frit, to attach the first and second substrates.

2. The method according to claim 1, further comprising drying the frit before the plasticizing of the frit.

3. The method according to claim 1, wherein the applying of the frit comprises screen-printing or dispensing.

4. The method according to claim 1, wherein the plasticizing of the frit comprises heating the frit to a temperature ranging from about 300° C. to about 700° C.

5. The method according to claim 1, wherein the laser beams have an intensity of from about 20 W to about 50 W.

6. A method of manufacturing an organic light emitting diode (OLED) display device including a first substrate having a pixel region, and a second substrate attached to the first substrate to seal the pixel region, the method comprising:
applying a frit paste to the second substrate;
applying a first laser beam to the frit paste, to form a plasticized frit;
aligning the first substrate and the second substrate; and
applying a second laser beam to the plasticized frit, to adhere the first substrate to the second substrate.

7. The method according to claim 6, wherein the applying of the laser beam to the frit paste comprises heating the frit to a temperature ranging from about 300° C. to about 700° C.

8. The method according to claim 6, wherein the first and second laser beams are infrared laser beams.

9. The method according to claim 6, wherein the first and second laser beams an intensity of from about 20 W to about 50 W.

10. The method according to claim 6, wherein the first and second laser beams are produced by a single laser source.

11. The method according to claim 6, wherein the applying of the first laser beam comprises removing moisture and/or binder elements from the frit paste.

12. The method according to claim 6, wherein the applying of the second laser beam comprises radiating the second laser beam through the first substrate, the second substrate, and/or between the first and second substrates.

13. The method according to claim 6, further comprising drying the frit paste, prior to the applying of the first laser beam.
